(19) United States
(12) Patent Application Publication
(10) Pub. No.: US 2014/0312737 A1
(43) Pub. Date: Oct. 23, 2014

(54) LAYER COMPOSITE COMPRISING ELECTROACTIVE LAYERS

(71) Applicants: Ludwig Jenninger Jenninger, Ahorn-Berolzheim (DE); Maria Jenninger, Ahorn-Berolzheim (DE)

(72) Inventors: Werner Jenninger, Koln (DE); Ludwig Jenninger, Ahorn-Berolzheim (DE); Maria Jenninger, Ahorn-Berolzheim (DE); Reimund Gerhard, Berlin (DE); Werner Wirges, Kleinmachnow (DE); Jürgen Maas, Detmold (DE); Christian Graf, Paderborn (DE); Harald Mundinger, Herscheid (DE)

(73) Assignee: Bayer Intellectual Property GmbH, Monheim (DE)

(21) Appl. No.: 14/002,175

(22) PCT Filed: Mar. 6, 2012
(86) PCT No.: PCT/EP12/53813

§ 371 Date: Nov. 8, 2013

(30) Foreign Application Priority Data
Mar. 7, 2011 (EP) 1157139.4

(51) Int. Cl. H01L 41/113; H01L 41/083; H01L 41/277

(52) U.S. Cl. CPC H01L 41/1132; H01L 41/277; H01L 41/083
USPC 310/319; 29/25.35; 310/311

(57) ABSTRACT

The invention relates to a multi-layer composite (2, 2.1, 2.2, 18) comprising at least two electroactive layers (4, 6) positioned between a first electrically conductive layer (12) and a second electrically conductive layer (14), wherein at least one electrically conductive sub-layer (8) is positioned between the at least two electroactive layers (4, 6), and wherein at least one of the at least two electroactive layers (4, 6) is a piezo layer (6), wherein at least one other of the at least two electroactive layers (4, 6) is a dielectric elastomer layer (4).

The invention relates to a multi-layer composite comprising at least two electroactive layers positioned between a first electrically conductive layer and a second electrically conductive layer, wherein at least one electrically conductive sub-layer is positioned between the at least two electroactive layers, and wherein at least one of the at least two electroactive layers is a piezo layer. The invention also relates to an electromechanical converter device comprising this multi-layer composite and to a method for producing a multi-layer composite.

Plastic composites are used in a large number of applications. For example, an appropriate multi-layer composite is used as a packaging material, insulating material or construction material. In addition to this conventional usage, multi-layer composites are increasingly being used as active components in sensor applications or for energy recovery or energy conversion, known as energy harvesting.

For example, WO 2010/066347 A2 discloses a multi-layer composite having multiple piezo layers, in other words layers made from a piezoelectric material. A piezoelectric material can be used to convert a mechanical force change acting on the multi-layer composite linearly into an electrical signal. Owing to their ability to convert a mechanical force change into an electrical quantity such as current, voltage or energy, piezo layers are suitable for a sensor application or for energy harvesting.

A multi-layer composite is used nowadays for example in structured pressure sensors for keyboards or touchpads, acceleration sensors, microphones, loudspeakers, ultrasonic converters for applications in medical engineering, marine engineering or for material testing.

A high-frequency transmitter having a piezoelectric element as a converter device is known for example from European patent EP 1 312 171 B1. Here the mechanical force change acting on the piezoelectric element is converted into electrical energy and used for autonomous operation of the high-frequency transmitter.

The disadvantage of the prior art, however, is that although a multi-layer composite having piezo layers with an elevated piezo constant is suitable for a sensor application and for energy harvesting, a corresponding piezo layer is of only limited suitability for an actuator application because the possible travel strokes are too small.

The object of the present invention is therefore to provide a multi-layer composite that is suitable not only for sensor and energy harvesting applications but also for actuator applications.

The object derived and described above is achieved according to a first aspect of the invention in a multi-layer composite comprising at least two electroactive layers positioned between a first electrically conductive layer and a second electrically conductive layer, wherein at least one electrically conductive sub-layer is positioned between the at least two electroactive layers, and wherein at least one of the at least two electroactive layers is a piezo layer, in that at least one other of the at least two electroactive layers is a dielectric elastomer layer.

In contrast to the prior art, according to the teaching of the invention the functions of sensor, actuator and energy harvesting are brought together in a single multi-layer composite according to the invention by means of at least two different types of electroactive layer.

The piezo layer can for example be formed from a suitable piezo polymer and be a piezo polymer film. According to a preferred embodiment the piezo layer can be a ferroelectret layer, such as a ferroelectret film. The piezo layer can have lasting piezoelectric properties. These can be produced for example by charging or polarising the piezo layer. With an elevated piezo constant a piezo layer can be used in particular for a sensor application and/or for energy harvesting. Piezo layers can be provided for example with a piezo constant of up to 1000 pC/N.

The multi-layer composite according to the invention includes furthermore at least one dielectric elastomer layer. A dielectric elastomer layer preferably has a relatively high dielectric constant. Furthermore, a dielectric elastomer layer preferably has a low mechanical rigidity. These properties lead to possible extension values of up to approximately 300%. A dielectric elastomer layer can be used in particular for an actuator application.

At least one electrically conductive sub-layer is positioned between the piezo layer and the dielectric elastomer layer. A sub-layer is understood to mean that electrically conductive material is present only in parts between the at least two electroactive layers. A structured or segmented layer for example can be formed. It shall be understood that the layer can also be a full layer.

Furthermore, an electrically conductive layer is positioned on the top side of the multi-layer composite and an electrically conductive layer on the underside of the multi-layer composite.

The electrically conductive layers can be designed in particular as an electrode. It shall be understood that the underside or top side may be coated only in parts with an electrically conductive layer.

An electrically conductive layer can preferably be formed from a material selected from the group comprising metals, metal alloys, conductive oligomers or polymers, conductive oxides and/or polymers filled with conductive fillers.

Through the combination according to the invention of at least one dielectric elastomer layer and at least one piezo layer the specific properties of the individual layer type can be brought together in a multi-layer composite. The result is a hybrid, compact multi-layer composite having sensor, actuator and energy harvesting functions.

The multi-layer composite can in principle have a large number of electroactive layers, provided that at least one piezo layer and at least one dielectric elastomer layer are included. According to a first embodiment of the multi-layer composite of the invention at least one further piezo layer can be positioned between the first electrically conductive layer and the second electrically conductive layer. More mechanical energy can be converted into electrical energy for example through the provision of two or more piezo layers. The piezo layers can be formed from the same or different materials. They can preferably be ferroelectret layers.

Alternatively or additionally, at least one further dielectric elastomer layer can be positioned between the first electrically conductive layer and the second electrically conductive layer. In an actuator application the possible change in thickness of a multi-layer composite can be adjusted and in particular increased. It should be noted that in the case of multiple electroactive layers an electrically conductive layer can preferably be positioned at least in part between all adjacent layers.

The piezo layer can be designed as a foamed polymer film or as a multi-layer system consisting of polymer films or polymer fabrics and can include a cellular hollow structure. Furthermore, according to a preferred embodiment the piezo layer can be formed from a polymer laminar structure. The polymer laminar structure can include cavities. For example, the cavities can contain a gas selected from the group comprising nitrogen, dinitrogen monoxide and/or sulfur hexafluoride. Structured piezo layers can comprise at least two closed outer layers and for example a porous or perforated middle layer.

Following an electrical charging or polarisation of the piezo layer, electrical charges of differing polarity can be distributed on the opposite surfaces of the cavities. Each cavity can form a dipole. If a mechanical force is exerted on a piezo layer, the dipole size and hence the dipole moment changes. A flow of current is generated between two electrodes attached to the two surfaces of the piezo layer. A piezo layer with a corresponding polymer laminar structure is particularly suitable for a sensor application and for energy harvesting.

According to a further embodiment of the multi-layer composite according to the invention the piezo layer can advantageously comprise a material selected from the group comprising polycarbonate, perfluorinated or partially fluorinated polymers and copolymers, polytetrafluoroethylene, fluoroethylene propylene, perfluoroalkoxyethylene, polyester, polyethylene terephthalate, polyethylene naphthalate, polyimide, polyetherimide, polyether, polymethyl (meth)acrylate, cyclic olefin polymers, cyclic olefin copolymers and/or polyolefins.

Furthermore, according to a preferred embodiment of the invention the dielectric elastomer layer can comprise a material selected for example from the group comprising polyurethane elastomers, silicone elastomers and/or acrylate elastomers.

A further aspect of the invention is an electromechanical converter device comprising a multi-layer composite described above. The converter device according to the invention can in particular be configured to convert a mechanical force change acting upon it into electrical energy or into an electrical signal and to change the geometrical shape accordingly on application of an electrical signal, in particular an electric field. As has already been stated, actuator, sensor and energy harvesting functions are brought together in a single device in an electromechanical converter device having a multi-layer composite described above. It shall be understood that an electromechanical converter device can have two or more multi-layer composites.

According to a first embodiment of the electromechanical converter device according to the invention the multi-layer composite can be connected to a user interface in such a way that a mechanical force change acting on the user interface is converted into an electrical signal. In other words a sensor function can be provided. The actuation of the user interface causes the multi-layer composite to change shape. The change in shape of the multi-layer composite generates a voltage, for example, which can be detected by appropriate means.

Alternatively or additionally, the multi-layer composite can be connected to a user interface in such a way that a mechanical force change acting on the user interface can be converted into electrical energy. The user interface can in particular be a surface, such as for example the pushbutton of a switch, which can be actuated by a user. The user interface can be connected to the multi-layer composite, in particular to an electrode of the multi-layer composite, in such a way that the force acting on the user interface also acts on the multi-layer composite. The mechanical force change, for example pressure from a user's finger, can then be converted into electrical energy or into an electrical signal.

According to a further embodiment of the electromechanical converter device according to the invention, a circuit arrangement that is electrically connectable to the multi-layer composite can be provided in order to further process a generated electrical signal or to use generated electrical energy. The circuit arrangement can be connected to the electrically conductive layers in an appropriate manner. The circuit arrangement can have analogue and/or digital components in order to further process an electrical signal, such as voltage or current, and/or to store electrical energy at least temporarily. A suitable capacitive element for example can be provided in the circuit arrangement as a storage device. The circuit arrangement can furthermore be configured in such a way that a voltage can be applied to at least some electrodes of the multi-layer composite. It shall be understood that the circuit arrangement can be designed according to the desired function of the electromechanical converter device.

According to a preferred embodiment of the electromechanical device according to the invention it can be provided for the circuit arrangement to be operable autonomously by means of the mechanical energy converted into electrical energy. In other words the circuit arrangement can be operated exclusively with the mechanical force change acting on the device, in particular independently of a further energy supply. No additional energy storage device for an additional energy supply is necessary. It shall be understood, however, that energy storage devices can be provided for the storage, in particular the temporary storage, of the electrical energy generated by the mechanical force change. For example, the generated electrical energy can be collected in a storage device such as a capacitor, a supercapacitor and/or a battery. This can be necessary if insufficient energy can be provided by a single actuation of the electromechanical converter device, with a multiple actuation being necessary instead. Once sufficient energy has been collected, a desired action can be carried out.

Alternatively the circuit arrangement can include an energy supply. An additional energy supply, in the form of an energy storage device for example, can be necessary if the electrical energy that can be generated by the multi-layer composite is insufficient to execute one or more desired actions. For example, the energy may not be sufficient because of a specified compact and in particular flat design of the multi-layer composite and/or because of the function to be executed.

The circuit arrangement can preferably be configured in such a way that the circuit arrangement can be shifted from an idle state to an operating state by the mechanical energy converted into electrical energy. In other words the circuit arrangement can be woken from a dormant state. It can then be supplied with energy from the energy storage device such as a battery. After executing the at least one action the circuit arrangement can be shifted (automatically) back to the idle state. The lifetime of an energy storage device can be extended significantly in this way. For example, a lifetime of 20 years can be achieved (using lithium-manganese dioxide batteries, for example). More extensive circuit arrangements comprising a processor, storage device and the like can be produced that are low-maintenance and have a long lifetime.

According to an advantageous embodiment the circuit arrangement can include a transmission element for transmitting a signal. In particular this can be a transmission element for sending out a radio signal such as a short pulse, a datagram or the like. A transmission element can have an antenna arrangement for example. A radio signal can for example be sent to a remote receiver. Said receiver can include an actuator and can control a consumer such as a heater or a lighting device, for example.

The radio signal can furthermore have a unique identifier, for example, which allows the transmitter, in other words the electromechanical converter device, to be identified. A corresponding device can be used for example in a security system or a personnel monitoring system. An operator can be located from the identifier.

In a converter device it is possible to trigger an action by means of a mechanical pressure. However, a user cannot be certain whether his touch has actually been registered, particularly if the converter device has very short actuator strokes. In order to provide a user with feedback that an actuation of the electromechanical converter device has actually been triggered, the multi-layer composite of the electromechanical converter device can according to a preferred embodiment be designed in such a way that a tactile feedback is given via the user interface. A tactile feedback can be given for example by means of a vibration and/or a (counter)pressure.

According to a further preferred embodiment of the electromechanical converter device according to the invention, for a tactile feedback a voltage can be applied to at least the one dielectric elastomer layer in such a way that a change in thickness of the elastomer layer of at least 0.1 μm, preferably at least 10 μm, is generated with a predefinable frequency. An electric field, in particular an alternating field, can be applied at least to the two electrodes positioned at the surfaces of the at least one dielectric elastomer layer. It has been recognised that if the electromechanical converter device is actuated with the user's finger, for example, the achievement of an adequate tactile feedback is dependent on the change in thickness and the frequency. It has been recognised in particular that in the frequency range between 200 and 250 Hz the human finger is at its most sensitive with a perception threshold of approximately 0.1 μm. In other frequency ranges a larger change in thickness can be achieved for example by the provision of multiple dielectric elastomer layers. A user receives a good tactile feedback even with short actuator strokes.

The user interface can furthermore be designed as a segment for triggering one or more actions. According to another embodiment the user interface can comprise a first segment for triggering a first action and at least a second segment for triggering a second action. For example, each segment can be connected to a separate multi-layer composite in order to trigger actions differently. It shall be understood that the operator controls can also be divided into three or more segments, for executing further actions for example.

According to a further embodiment the electromechanical converter device can be a sensor device such as a switch device. For example, the electromechanical converter device can be a tactile sensor, a flat sensor or a floor sensor.

Tactile sensors of the conventional design can preferably be formed with two or more piezo layers. This allows actuator strokes of up to approximately 2 mm, for example. Furthermore, two or more piezo layers allow forces of up to approximately 5 N, for example. With actuator strokes of for example up to approximately 2 mm and forces of up to approximately 5 N a sufficiently large, temporarily stored, electrical energy can be generated by means of a mechanical and electrical adjustment, with the aid of which an autonomous tactile sensor, such as a wireless rocker button, can be operated.

For a visually attractive and in particular a flat design, flat sensors can have just one piezo layer and one dielectric elastomer layer. In such flat sensors (imperceptible) actuator strokes of less than 500 μm can be achieved. A flat sensor can be actuated with a force of less than 1 N. A tactile feedback as confirmation of an operation of the flat sensor can be provided in particular through the dielectric elastomer layer. In addition to a tactile feedback, feedback signals can be transferred from the element to be actuated to the user. For example, a radio signal can be sent.

A further possible application of the electromechanical device is a floor sensor such as an intelligent floor element (smart carpet). The device can be formed for example in the form of a tile, which can have a surface area of 100 cm² or more, for example. The tile can moreover have a depth of approximately 1 mm. This floor element can in particular have multiple piezo layers. An operating force of approximately 100 N and more is possible. Energy quantities of more than 300 μJ can be achieved in this way. In addition to the energy recovery function, the multi-layer composite can be used as a sensor element to locate an operator who treads on a tile for example.

A tactile sensor, a flat sensor or a floor sensor can be used for example in a building automation system or in personnel monitoring, such as patient monitoring. Under mechanical loading the corresponding sensors can send a signal to one or more receivers, for example. The signal received can then be processed and an action, such as an alarm, triggered, or a consumer can be activated or deactivated.

For example, a large number of floor sensors can be provided in a building and a unique identifier assigned to each sensor. In a monitoring system users can be located by a process in which when a sensor is actuated it sends its identifier to a processing device, which allows the position of the sensor and hence of the operator to be inferred.

Provided that the electrical output variables are reproducible and offer long-term stability and correlate with the weight of a person or an object for example, the measured “weight” could be integrated into a radiogram to provide additional information about people or vehicles on an intelligent floor. This gives rise to interesting applications in gerontology for example and in all forms of AAL (ambient assisted living).

A tactile sensor can also be used in a key, such as a car key or a door key, in order for example to unlock a corresponding device by wireless. A corresponding car key for example can be used autonomously.

It shall be understood that according to further variants, the multi-layer composite according to the invention or the electromechanical device according to the invention can also be used for other applications, such as in structured pressure sensors for keyboards or touchpads, acceleration sensors, microphones, loudspeakers, ultrasonic converters for applications in medical engineering, marine engineering or for material testing. An application as mechanical pressure sensors in general is also possible in automation engineering and automotive engineering, in the latter case as steering wheel sensors or seat sensors for example.

The high sensitivity of the materials that are preferably used also allows a sensor to be used underneath an only slightly yielding but otherwise rigid plate. This feature is utilised in for example anti-vandal keypads having a thin steel plate, such as are manufactured by Screentec (Finland) for example, but could also be used for example in the aforementioned “smart carpet” sensor applications.

A further aspect of the invention is a method for producing a multi-layer composite having at least two electroactive layers positioned between a first electrically conductive layer and a second electrically conductive layer, wherein at least one electrically conductive sub-layer is positioned between the at least two electroactive layers, wherein at least one of the at least two electroactive layers is a piezo layer, and wherein at least one other of the at least two electroactive layers is a dielectric elastomer layer. The method comprises the steps of provision of at least one piezo layer, provision of at least one dielectric elastomer layer, connection of the piezo layer to the dielectric elastomer layer, wherein before connecting the piezo layer to the dielectric elastomer layer at least one electrically conductive layer is applied to the piezo layer and/or to the dielectric elastomer layer.

The piezo layer that is provided can for example preferably be provided at least in part with an electrically conductive layer on both sides. The dielectric elastomer layer can then preferably be connected directly to at least one of these electrically conductive layers. In a further step the dielectric elastomer layer can furthermore be provided at least in part with a further electrically conductive layer. It shall be understood that the dielectric elastomer layer can preferably first be coated with electrically conductive layers on both sides. The piezo layer can then be applied subsequently.

It shall further be understood that according to further variants of the invention, further piezo layers and/or further dielectric elastomer layers can be positioned in further steps. For example, a multi-layer composite comprising at least one piezo layer and one dielectric elastomer layer, which are positioned between two electrically conductive layers, can be cascaded with a multi-layer composite of the same construction.

Furthermore, according to a first embodiment of the method according to the invention the dielectric elastomer layer or the piezo layer can be laminated to the electrically conductive layer. This leads in a simple manner to a particularly good contact between the corresponding layers.

According to a preferred embodiment of the method according to the invention the dielectric elastomer layer or the piezo layer can be printed at least in part with a conductive layer. For example, a structured electrode can be printed. A printing method can be performed in a simple manner. In particular, a mass production of a multi-layer composite is possible with an elevated rate of production.

There are now a large number of possibilities for embellishing and further developing the multi-layer composite according to the invention, the electromechanical converter device according to the invention and the method according to the invention for producing a multi-layer composite. In this regard reference is made firstly to the subordinate claims following the independent claims and secondly to the description of embodiment examples in conjunction with the drawings. The drawings are as follows:

FIG. 1 shows a schematic view of a first embodiment example of a multi-layer composite according to the present invention;

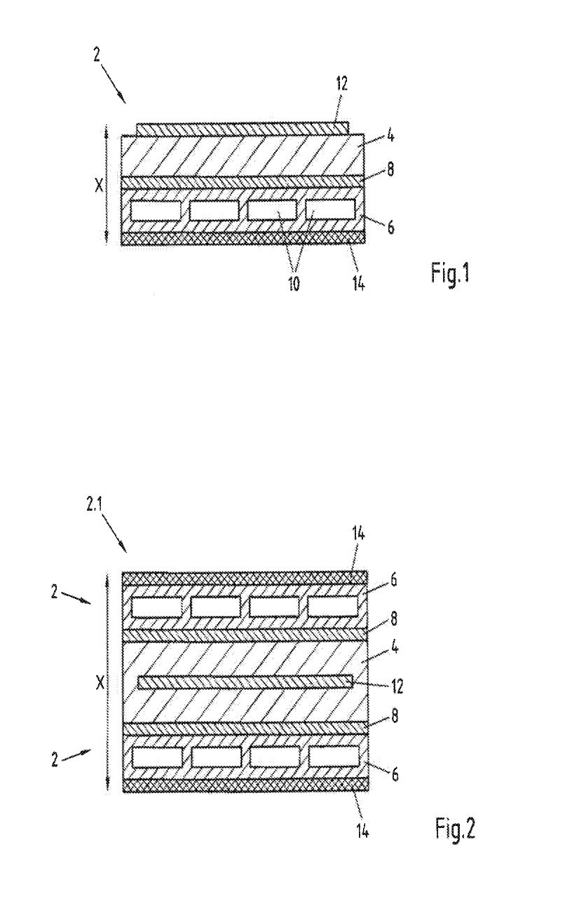

FIG. 2 shows a schematic view of a second embodiment example of a multi-layer composite according to the present invention;

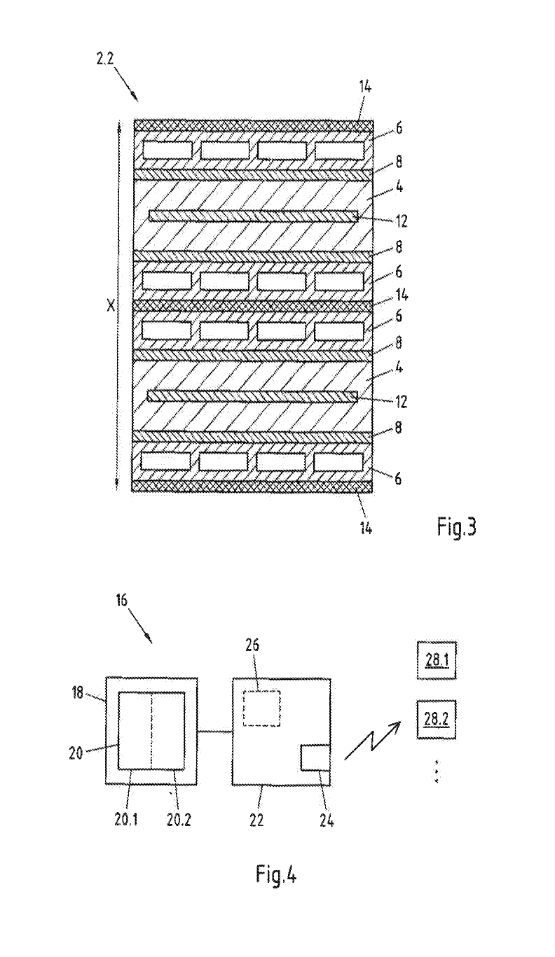

FIG. 3 shows a schematic view of a third embodiment example of a multi-layer composite according to the present invention;

FIG. 4 shows a schematic view of a first embodiment example of an electromagnetic converter device according to the present invention;

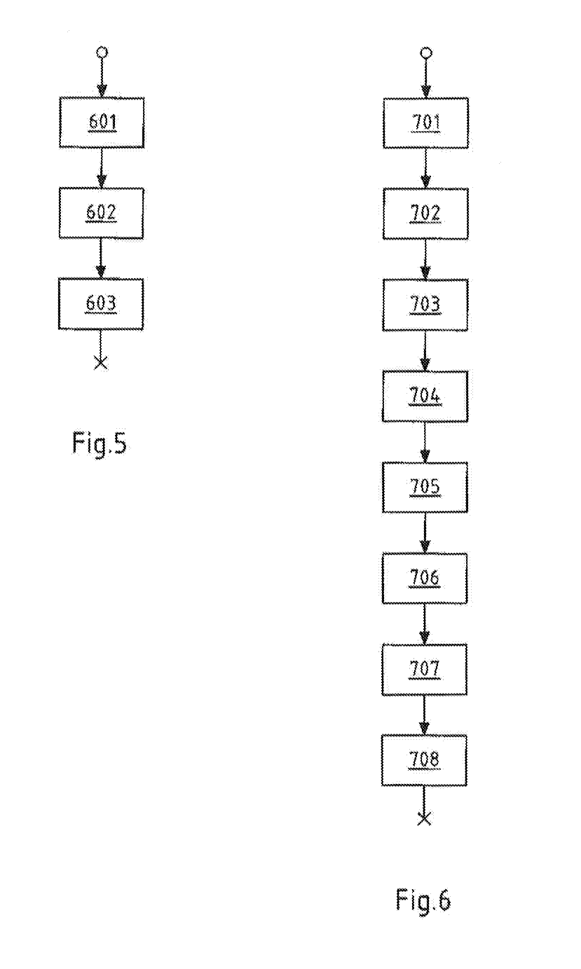

FIG. 5 shows a flow chart of a first embodiment example of a method for producing a multi-layer composite according to the present invention;

FIG. 6 shows a flow chart of a second embodiment example of a method for producing a multi-layer composite according to the present invention.

Identical reference numerals are used hereafter for identical elements.

FIG. 1 shows a schematic view of a first embodiment example of a multi-layer composite 2 according to the present invention. The illustrated multi-layer composite 2 comprises two electroactive layers 4 and 6.

The electroactive layer 4 is a dielectric elastomer layer 4. A dielectric elastomer layer 4 advantageously has a relatively high dielectric constant. Furthermore, a dielectric elastomer layer 4 advantageously has a low mechanical rigidity. This leads to possible extension values of up to approximately 300%. A dielectric elastomer layer 4 can be used in particular for an actuator application.

The second electroactive layer 6 is formed as a piezo layer 6. The illustrated piezo layer 6 can be formed for example from a suitable piezo polymer and can be a piezo polymer film or a ferroelectret film, for example. The illustrated piezo layer 6 has a polymer laminar structure. The polymer laminar structure has (intentionally) incorporated cavities 10.

In order to produce the cavities 10 a flat polymer layer and a wave-shaped polymer layer can be provided for example, which are connected to each another at the wave troughs. In an alternative embodiment of the piezo layer 6 two flat polymer layers can be connected by means of ribs to form the cavities 10.

The piezo layer 6 can be electrically charged before the piezo layer 6 is positioned in the multi-layer composite 2. Electrical charging or polarisation can be performed for example by direct charging or by corona discharge. The charging or polarisation gives the piezo layer 6 lasting piezoelectric properties. A piezo layer 6 can be used in particular for a sensor application and/or for energy harvesting.

It can further be inferred from FIG. 1 that at least one electrically conductive sub-layer 8 is positioned between the dielectric elastomer layer 4 and the piezo layer 6. It shall be understood that multiple layers and/or a full layer can also be positioned. This conductive layer 8 can preferably be connected face-to-face to the dielectric elastomer layer 4 and/or the piezo layer 6. The electrically conductive sub-layer 8 can be designed in particular as an electrode. The electrode can be formed for example from a metal, a metal alloy, a conductive oligomer or polymer, a conductive oxide and/or a polymer filled with conductive fillers.

The two electroactive layers 4 and 6 are furthermore positioned between two further electrically conductive layers 12 and 14.

The layer 14 is applied on top of the piezo layer 6 and can in particular cover virtually the entire surface of the piezo layer 6. The electrically conductive layer 12 can be applied on top of the dielectric elastomer layer 4. A segmented layer 12 can be provided, for example. The electrically conductive layers 12 and 14 too are preferably formed on the basis of metals.

The hybrid multi-layer composite 2 comprising at least one dielectric elastomer layer 4 and at least one piezo layer 6 is characterised in particular in that three functions can be combined and made available in a single multi-layer composite. In particular the functions of actuator, energy harvesting and sensor are provided by a single multi-layer composite.

Whereas in a dielectric elastomer layer the surface area of the layer changes when an electric field is applied, in a ferroelectret film (only) the thickness of the layer changes substantially. The configuration of the two types of layer means that a change in shape is achievable substantially only in a direction X perpendicular to the surface of the layers 4 and 6. Thus the thickness of the multi-layer composite 2 can be changed, in other words increased or reduced, without a substantial change in shape being possible in another direction. It should be noted that a change in shape in another direction can be permissible, depending on the application.

FIG. 2 furthermore shows a further embodiment of a multi-layer composite 2.1 according to the present invention. As can be inferred from FIG. 2, the multi-layer composite 2.1 has two multi-layer composites 2 according to FIG. 1. In particular the multi-layer composites 2 are positioned on top of each other in a mirror-inverted configuration. It shall be understood that only one electrically conductive layer 12 can be provided or that the two layers 12 of the multi-layer composites 2 can be connected to each other to form one layer 12.

FIG. 3 shows a third embodiment example of a multi-layer composite 2.2 according to the present invention. The multi-layer composite 2.2 comprises for example two cascaded multi-layer composites 2.1 according to FIG. 2. It shall be understood that further cascades are possible. It shall further be understood that only one layer 14 can be provided or that the two layers 14 of the multi-layer composites 2.2 can be connected to each other to form one layer 14.

It shall also be understood that according to other variants of the present invention a composite layer can be constructed in any other form provided that at least one dielectric elastomer layer and at least one piezo layer are provided. For example, two or more piezo layers with one (or more) elastomer layer(s) can be provided.

FIG. 4 shows a simplified view of an embodiment example of an electromechanical converter device 16 according to the present invention. The electromechanical converter device 16 can be designed for example as a switch, such as a tactile sensor, a flat sensor, or as an intelligent floor element. In particular the converter device 16 can be used in a building automation system. Thus the converter device 16 can be used to control heaters, lighting, shading equipment, etc., or in gerontology (activity and fall detection) or in security technology.

The electromechanical converter device 16 comprises a multi-layer composite 18 which in the interests of a better illustration is not shown in detail. A multi-layer composite 2, 2.1 or 2.2 according to FIGS. 1 to 3 can be used for example.

The design of the multi-layer composite 18 can be governed in particular by the application of the electromechanical converter device 16.

Tactile sensors of the conventional design can preferably be formed with two or more piezo layers 6. This allows actuator strokes of up to approximately 2 mm, for example. Furthermore, two or more piezo layers 6 mean that mechanical forces of for example up to approximately 5 N can be converted into electrical energy.

By contrast, flat sensors can have as small as possible a number of layers and/or layers with low thicknesses. For example, a flat sensor can have one piezo layer and one dielectric elastomer layer. In such flat sensors (imperceptible) actuator strokes of less than 500 μm are achieved. A flat sensor can be actuated with a force of less than 1 N. A tactile feedback as confirmation of an operation of the flat sensor can be provided in particular by applying a voltage to the dielectric elastomer layer. In addition to a tactile feedback, feedback signals can be transferred from the element to be actuated to the user. This can take place via a radio signal, for example.

A further possible application of the converter device 16 is a floor sensor such as an intelligent floor element. The converter device 16 can be formed for example in the form of a tile, which can have a surface area of 100 cm² or more, for example. The tile can moreover have a depth of approximately 1 mm. This floor element can in particular have multiple piezo layers. An operating force of 100 N and more is possible. Energy quantities of more than 300 μJ can be achieved in this way.

The multi-layer composite 18, in particular the top electrode, can be connected to a user interface 20. A user interface is understood to be the surface that can be actuated by a user, in other words have a pressure applied to it for example, in order to bring about a desired function.

The user interface 20 can in principle be designed in any way. For example, the user interface 20 can have a first segment 20.1 and a second segment 20.1, which can for example differ from each other visually. The first segment 20.1 can be provided for a first action and the second segment 20.2 for a second action. It shall be understood that more than just two segments or more than just one segment can also be provided.

A circuit arrangement 22 can be connected to the multi-layer composite 18. The circuit arrangement 22 can be connected to the electrodes of the multi-layer composite 18. The circuit arrangement 22 and the multi-layer composite 18 can be integrated in a housing (not shown) or be of a modular construction. A modular construction allows for example a flexible combination of different elements to achieve different functions.

The circuit arrangement 22 can be set up to bring about actions on the basis of electrical signals that are ascribed to an actuation of the electromechanical converter device. For example, a transmission element 24 can be provided in the circuit arrangement 22. On receipt of an electrical signal from the multi-layer composite 18 this transmission element 24 can cause an item of information to be sent out. A radio signal can be sent out in particular. It shall be understood that a wired interface can also be provided as an alternative or in addition.

The information that is sent out can be received by one or more receivers 28.1, 28.2. The receivers 28.1, 28.2 can comprise actuators or can be connected to actuators in order to control consumers (not shown), depending on the information received. As has already been described, a heater or the like can be controlled for example. Furthermore, the information received, such as a unique identifier for example, can allow the position of an operator to be inferred.

One possibility for supplying the circuit arrangement 22 with energy to generate a radio signal for example consists in using the mechanical force acting on the user interface 20. As has already been described, piezo layers 6 in particular are suitable for energy harvesting. In the tactile sensor described above, for example, the mechanical energy that is converted into electrical energy can be sufficient to send a radio signal. In particular it is possible to collect the electrical energy generated and to store it temporarily for example by means of a capacitor, a supercapacitor or a battery. Once a sufficient amount of energy has been stored to perform an action, this action can be executed. An autonomous electromechanical converter device 16 can be provided.

The circuit arrangement 22 can optionally include an energy storage device 26 such as a battery. An energy storage device 26 can be necessary in particular if the electrical energy that can be generated by the mechanical force change is not sufficient for an autonomous operation of the circuit arrangement 22. This is the case with flat sensors, for example, which can only comprise one piezo layer 6 for example. An energy of approximately 100 pJ can be generated, for example, having regard to the available space. This energy can be used to shift the circuit arrangement 22 from an idle state to an operating state, in other words to wake it up. The circuit arrangement 22 can then be supplied with energy by the energy storage device 26 in order to execute at least one desired function. The circuit arrangement can then preferably be shifted automatically back to the idle state.

In such an electromechanical converter device 16 the standby current consumption is close to the self-discharge of the energy storage device 26. The wake-up energy can be generated exclusively by the mechanical force change. A lifetime of more than 20 years for example can be achieved (using lithium-manganese dioxide batteries for example).

An energy storage device can moreover be necessary if the operations to be performed by the circuit arrangement require more energy than can be provided by the mechanical force change. It shall be understood here that the circuit arrangement can include further components, such as a processor, storage device or interfaces.

The circuit arrangement 22 can moreover be connected to at least the electrodes of a dielectric elastomer layer 4 in such a way that an electric field can be applied for an actuator application in order to produce a change in thickness. For example, a tactile feedback can be given to a user by the actuator function of the electromechanical converter device 16. Thus an alternating field with a frequency of 200 to 250 Hz can be generated. A change in thickness of the electromechanical converter device 16 of at least 0.1 μm, preferably 10 μm, can be generated for example by this alternating field. It has been recognised that the human finger is particularly sensitive at precisely these parameter values.

FIG. 5 shows a first embodiment example of a method for producing a multi-layer composite according to the invention.

In a first step 601 a piezo layer 6, such as for example a ferroelectret film, can be provided. In a second step 602 an electrically conductive sub-layer 8 can be applied to at least one side of the piezo layer 6, by coating for example. Then in a step 603 a provided dielectric elastomer layer 4 can be applied, by lamination for example, to the at least one electrically conductive layer 8. A multi-layer composite 2.1 having a piezo layer 4 and a dielectric elastomer layer 6 can be produced in a simple manner.

It shall be understood that the sequence of the processing steps can in principle be arbitrary. In particular, as an alternative, a dielectric elastomer layer 4 can be provided in a first step, which can then first be provided with an electrically conductive layer 8. A piezo layer 6 can then be provided subsequently.

FIG. 6 shows a further embodiment example of a method for producing a multi-layer composite according to the invention.

In a first step 701 a piezo layer 6, such as a ferroelectret film, can first be provided.

In a second step 702 the piezo layer 6 can be coated on preferably both sides with electrically conductive layers 8, 14. In particular the piezo layer 6 can be coated over the entire surface on both sides. In addition to the full-surface coating the piezo layer can also be coated only in parts with an electrically conductive layer 8 or 14 respectively. A structured electrode can be produced. Active and passive areas can be created in this way in particular.

Then in step 703 a dielectric elastomer layer 4, in particular an elastomer film, can be laminated onto the top or bottom electrically conductive layer 8, 14.

It can be preferable for the dielectric elastomer layer 4 to be laminated (only) in parts. This can be advantageous in particular because of the different extension values of the dielectric elastomer layer 4 and the piezo layer 6.

In the next step 704 the dielectric elastomer layer 4 can in turn be printed on its top side with a preferably segmented electrically conductive layer 12, such as a structured electrode. A structured electrode is characterised in particular by passive and active areas. In the subsequent operation of the multi-layer composite 2 it can be isolated from the earthing point in this way.

This multi-layer composite 2 can furthermore be connected in a mirror-inverted configuration to a multi-layer composite 2 of the same construction, in particular by lamination (step 706). The layers 12 can be connected to each other for example.

Multi-layer composites can optionally be produced by cascading two or more of these multi-layer composites 2.1 (step 707). For example, two multi-layer composites 2.1 can be cascaded by stacking, gluing or laminating.

In a further step 708 the multi-layer composite that has been produced can be brought into a desired shape with predefinable dimensions. For example, individual multi-layer composites can be punched out.

In a further method the multi-layer composite produced can then be electrically connected to a circuit arrangement. In particular the circuit arrangement can be connected to the electrically conductive layers designed as electrodes.

It shall be understood here too that according to other variants of the present invention a different sequence of steps is possible and that this can be dependent in particular on the specific embodiment of the multi-layer composite. For example, two identical layers can first be connected to each other and only then another type of layer applied.

1. Multi-layer composite (2, 2.1, 2.2, 18), comprising:
at least two electroactive layers (4, 6) positioned between a first electrically conductive layer (12) and a second electrically conductive layer (14),
wherein at least one electrically conductive sub-layer (8) is positioned between the at least two electroactive layers (4, 6), and
wherein at least one of the at least two electroactive layers (4, 6) is a piezo layer (6),
characterised in that
at least one other of the at least two electroactive layers (4, 6) is a dielectric elastomer layer (4).

2. Multi-layer composite (2, 2.1, 2.2, 18) according to claim 1, characterised in that
at least one further piezo layer (6) is positioned between the first electrically conductive layer (12) and the second electrically conductive layer (14),
and/or
at least one further dielectric elastomer layer (4) is positioned between the first electrically conductive layer (12) and the second electrically conductive layer (14).

3. Multi-layer composite (2, 2.1, 2.2, 18) according to claim 1 or 2, characterised in that the piezo layer (6) is a ferroelectret layer.

4. Multi-layer composite (2, 2.1, 2.2, 18) according to one of the preceding claims, characterised in that
the piezo layer (6) comprises a material selected from the group comprising polycarbonate, perfluorinated or partially fluorinated polymers and copolymers, polytetrafluoroethylene, fluoroethylene propylene, perfluoroalkoxyethylene, polyester, polyethylene terephthalate, polyethylene naphthalate, polyimide, polyetherimide, polyether, polymethyl (meth)acrylate, cyclic olefin polymers, cyclic olefin copolymers and/or polyolefins,
and/or
the dielectric elastomer layer (4) comprises a material selected from the group comprising polyurethane elastomers, silicone elastomers and/or acrylate elastomers.

5. Electromechanical converter device (16) comprising a multi-layer composite (2, 2.1, 2.2, 18) according to one of the preceding claims 1 to 4.

6. Electromechanical converter device (16) according to claim 5, characterised in that the multi-layer composite (2, 2.1, 2.2, 18) is connected to a user interface (20) in such a way that a mechanical force change acting on the user interface (20) can be converted into an electrical signal and/or into electrical energy.

7. Electromechanical converter device (16) according to claim 5 or 6, characterised in that an electrical circuit arrangement (22) connectable to the multi-layer composite (2, 2.1, 2.2, 18) is provided.

8. Electromechanical converter device (16) according to one of the preceding claims 5 to 7, characterised in that
the circuit arrangement (22) can be operated autonomously by the mechanical energy converted into electrical energy,
or
the circuit arrangement (22) comprises a power supply (26) wherein the circuit arrangement (22) can be shifted from an idle state to an operating state by the mechanical energy converted into electrical energy.

9. Electromechanical converter device (16) according to one of the preceding claims 5 to 8, characterised in that the circuit arrangement (22) comprises a transmission element (24) for transmitting a signal.

10. Electromechanical converter device (16) according to claim 9, characterised in that for a tactile feedback a voltage is applied to at least the one dielectric elastomer layer (4) in such a way that a change in thickness of the multi-layer composite (2, 2.1, 2.2, 18) of at least 0.1 μm is generated with a predefinable frequency.

11. Electromechanical converter device (16) according to one of claims 5 to 10, characterised in that the user interface (20) comprises a first segment (20.1) for triggering a first action and at least a second segment (20.2) for triggering a second action.

12. Electromechanical converter device (16) according to one of claims 5 to 11, characterised in that the electromechanical converter device (16) is a mechanical pressure sensor, in particular a tactile sensor, a flat sensor or a floor sensor.

13. Method for producing a multi-layer composite (2, 2.1, 2.2, 18) having at least two electroactive layers (4, 6) positioned between a first electrically conductive layer (12) and a second electrically conductive layer (14), wherein at least one electrically conductive sub-layer (8) is positioned between the at least two electroactive layers (4, 6), wherein at least one of the at least two electroactive layers (4, 6) is a piezo layer (6), and wherein at least one other of the at least two electroactive layers (4, 6) is a dielectric elastomer layer (4), comprising:
provision of the at least one piezo layer (6),
provision of the at least one dielectric elastomer layer (4),
connection of the piezo layer (6) to the dielectric elastomer layer (4),
wherein before connecting the piezo layer (6) to the dielectric elastomer layer (4) at least the one electrically conductive sub-layer (8) is applied to the piezo layer (6) and/or to the dielectric elastomer layer (4).

14. Method according to claim 13, characterised in that the dielectric elastomer layer (4) or the piezo layer is laminated to the electrically conductive sub-layer (8).

15. Method according to one of claims 13 or 14, characterised in that the dielectric elastomer layer (4) or the piezo layer (6) is printed at least in part with the conductive layer (12, 14).
